(19) United States
(12) Patent Application Publication
(10) Pub. No.: US 2008/0212285 A1
(43) Pub. Date: Sep. 4, 2008

(54) ELECTRONIC EQUIPMENT AND HEAT DISSIPATING DEVICE IN THE ELECTRONIC EQUIPMENT

(75) Inventor: ZHENG-HENG SUN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/944,425

(22) Filed: Nov. 22, 2007

(30) Foreign Application Priority Data
Mar. 1, 2007 (CN) 200710200245.9

(51) Int. Cl. H05K 7/20; F28F 3/06

(52) U.S. Cl. 361/710; 165/185

(57) ABSTRACT

An electronic equipment includes a chassis, and a heat dissipating device. The chassis includes a sidewall defining an opening therein. The heat dissipating device includes a plate fixed to the sidewall of the chassis, and a plurality of parallel fins perpendicularly projecting from one side of the plate. The fins are exposed out of the chassis from the opening. Each two of the fins defines a channel therebetween, and the plate defines a plurality of vents therein communicating with each of the channels.

### BACKGROUND

1. Field of the Invention

The present invention relates to an electronic equipment and a heat dissipating device used in the electronic equipment.

2. Description of Related Art

An electronic equipment, such as a computer chassis, usually defines a plurality of vents in sidewalls thereof, and a heat sink and a system fan are usually installed on an electronic component in the computer chassis for dissipating heat. However, because the heat sink is installed on the electronic component directly in the computer chassis, the heat in the computer chassis is difficult to be exhausted by the heat sink and the vents in the sidewall.

What is needed, therefore, is an electronic equipment and a heat dissipating device used in the electronic equipment which are able to dissipate heat quickly and efficiently.

### SUMMARY

An exemplary electronic equipment includes a chassis, and a heat dissipating device. The chassis includes a sidewall defining an opening therein. The heat dissipating device includes a plate fixed to the sidewall of the chassis, and a plurality of parallel fins perpendicularly projecting from one side of the plate. The fins are exposed out of the chassis from the opening. Each two of the fins defines a channel therebetween, and the plate defines a plurality of vents therein communicating with each of the channels.

Other advantages and novel features will become more apparent from the following detailed description of embodiments when taken in conjunction with the accompanying drawings, in which:

### BRIEF DESCRIPTION OF THE DRAWINGS

FIG. 1 is an exploded, isometric view of an electronic equipment in accordance with a first embodiment of the present invention;

FIG. 2 is a partially assembled view of FIG. 1, but viewed from another aspect;

FIG. 3 is an assembled view of FIG. 1; and

FIG. 4 is an exploded, isometric view of an electronic equipment in accordance with a second embodiment of the present invention.

### DETAILED DESCRIPTION

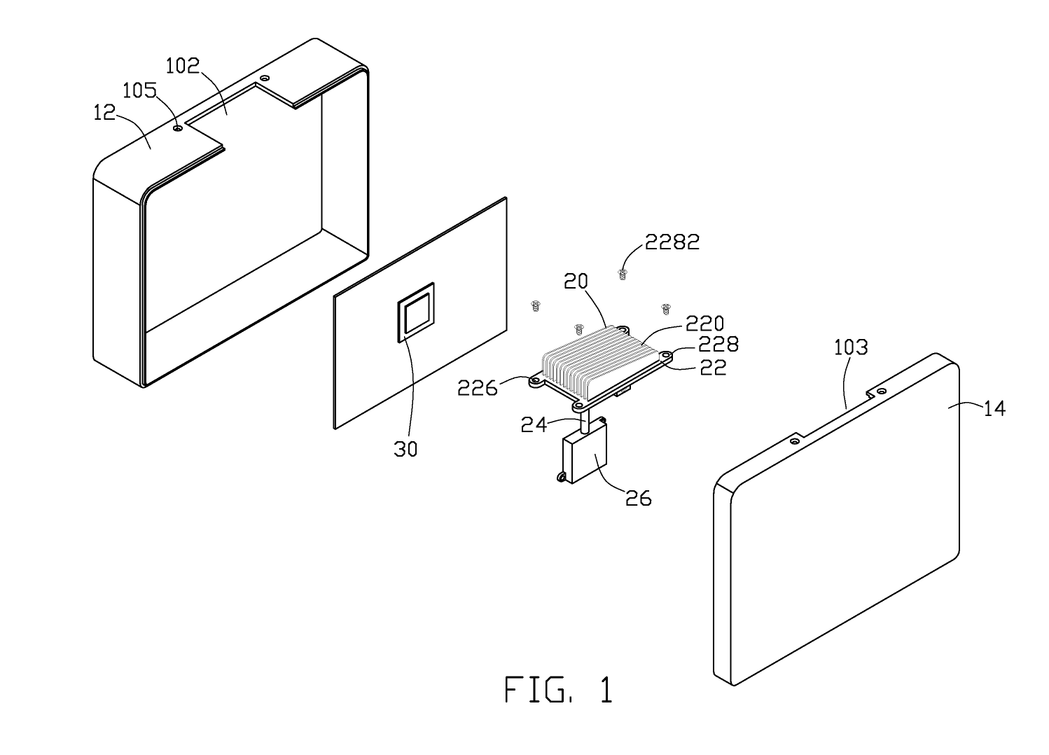

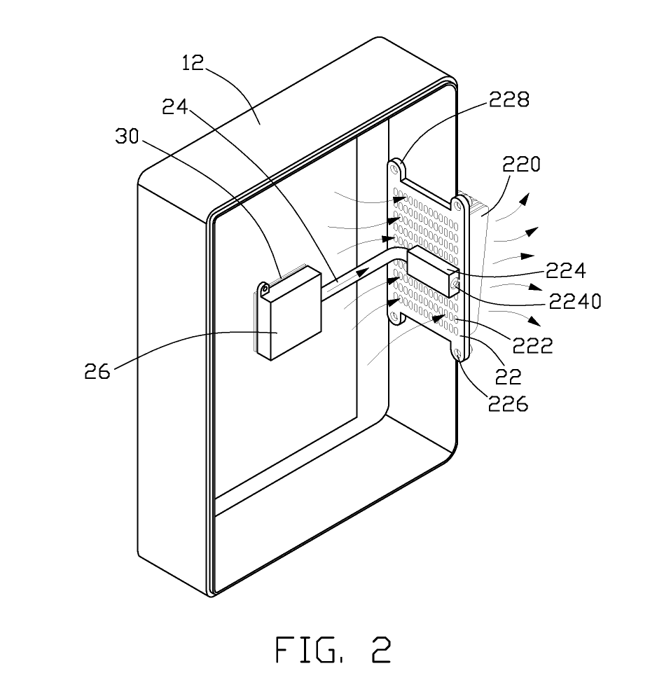

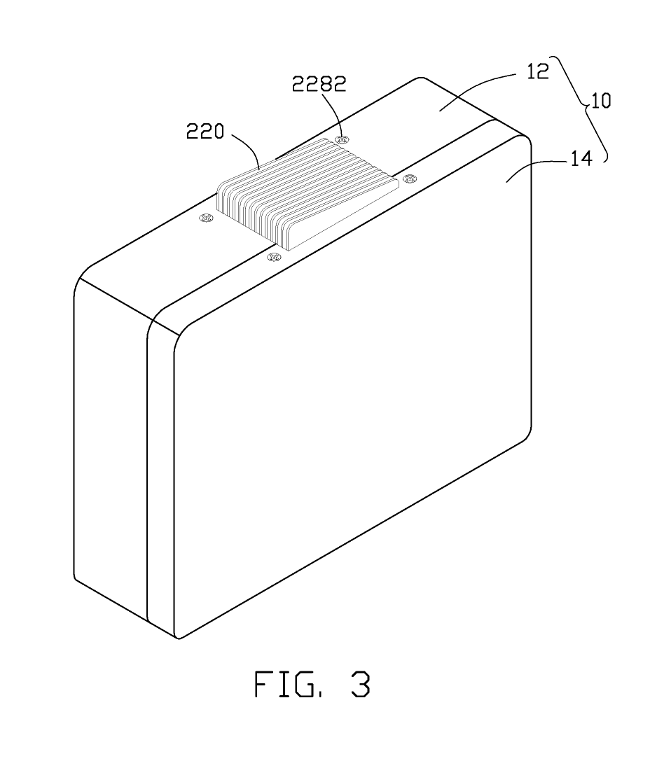

Referring to FIGS. 1 to 3, an electronic equipment is provided in accordance with a first embodiment of the present invention. The electronic equipment includes a chassis 10, and a heat dissipating device 20 detachably mounted on the chassis 10.

The chassis 10 includes a base 12 receiving an electronic device 30, and a cover 14. A sidewall of the base 12 defines an opening 102, and two fixing holes 105 adjacent to two ends of the opening 102 respectively. A sidewall of the cover 14 adjoining the sidewall of the base 12 defines an opening 103 communicating with the opening 102 of the base 12. Two fixing holes 105 are defined in the sidewall of the cover 14 adjacent to two ends of the opening 103 respectively.

The heat dissipating device 20 includes a plate 22, and a plurality of parallel fins 220 perpendicularly projecting from one side of the plate 22. Each two of the fins 220 define a channel therebetween, and the plate 22 defines a plurality of vents 222 in communication with each channel. A heat conductive block 224 is formed on an opposite side of the plate 22, and a through slot 2240 parallel to the plate 22 is defined in the block 224. One end of a generally L-shaped heat pipe 24 coated with tin paste or tinfoil is inserted into the through slot 2240 of the block 224, and the other end of the heat pipe 24 is connected to a heat absorbing block 26. The tin paste or the tinfoil between the heat pipe 24 and the block 224 is used to reduce the thermal resistance between the heat pipe 24 and the fins 220, thereby improving heat conductivity between the heat pipe 24 and the fins 220. Four tabs 228 each defining a through hole 226 therein, extend from four corners of the plate 22 respectively.

In assembly, the heat dissipating device 20 is attached to the sidewall of the base 12 of the chassis 10, with some of the fins 220 of the heat dissipating device 20 being exposed out from the opening 102 of the base 12, the plate 22 contacting the inside surface of the sidewall of the base 12, and two of the through holes 226 aligning with the fixing holes 105 of the base 12. Two screws 2282 are extended through the fixing holes 105 of the base 12 and then engage in the corresponding through holes 226 of the plate 22, thereby the heat dissipating device 20 is fixed to the base 12 of the chassis 10, and the heat absorbing block 26 of the heat dissipating device 20 contacts with the electronic device 30 in the chassis 10. Thereafter, the cover 14 is fixed to the base 12 of the chassis 10, with the other of the fins 220 being exposed out from the opening 103 of the cover 14, and the other two of the through holes 226 of the plate 22 aligning with the fixing holes 105 of the cover 14. Two screws 2282 are extended through the fixing holes 105 of the cover 14 and then engage in the corresponding through holes 226 of the plate 22, thereby the heat dissipating device 20 is fixed to the cover 14 of the chassis 10.

When the electronic equipment is in use, heat is generated by the electronic device 30 and other electronic components in the chassis 10. With the assistance of a system fan, a portion of the heat is exhausted out through the vents 222 of the plate 22 and the fins 220, and the other portion of the heat is conducted to the fins 220 through the heat absorbing block 26 and the heat pipe 24, and then dissipated by the fins 220.

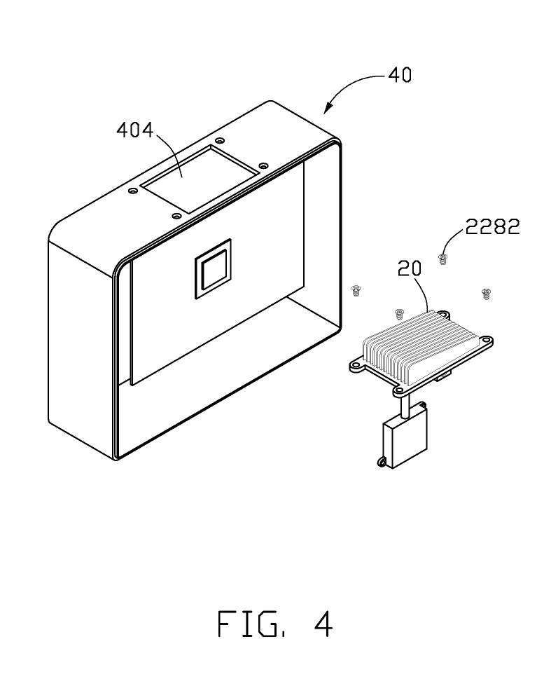

Referring to FIG. 4, an electronic equipment is provided in accordance with a second embodiment of the present invention. The electronic equipment includes a chassis 40, and a heat dissipating device 20 detachably mounted on the chassis 40. The heat dissipating device 20 is the same as the heat dissipating device 20 of the first embodiment. A sidewall of the chassis 40 defines an opening 404. Four fixing holes are defined in the sidewall of the chassis 40 adjacent to four corners of the opening 404. Four screws 2282 are extended through the fixing holes of the chassis 40 and then engage in the corresponding through holes of the heat dissipating device 20, thereby the heat dissipating device 20 is fixed to the chassis 40, with the fins of the heat dissipating device 20 being exposed out from the opening 404 of the chassis 40.

It is believed that the present embodiments and their advantages will be understood from the foregoing description, and it will be apparent that various changes may be made thereto without departing from the spirit and scope of the invention or sacrificing all of its material advantages, the example hereinbefore described merely being preferred or exemplary embodiments of the invention.

What is claimed is:

1. An electronic equipment comprising:
a chassis receiving at least one electronic device therein, the chassis comprising a sidewall, the sidewall defining an opening therein; and
a heat dissipating device for dissipate heat generated by the electronic device, the heat dissipating device comprising a plate fixed to the sidewall of the chassis, and a plurality of parallel fins perpendicularly projecting from one side of the plate, the fins exposed out of the chassis from the opening of the chassis to receive air outside the chassis, each two of the fins defining a channel therebetween, and the plate defining a plurality of vents therein communicating with each of the channels.

2. The electronic equipment as claimed in claim 1, wherein the chassis comprises a base and a cover, the opening is defined partially in the base, and partially in the cover.

3. The electronic equipment as claimed in claim 1, wherein four tabs each defining a through hole therein extend from four corners of the plate respectively, the sidewall of the chassis defines four fixing holes adjacent to the opening, four screws are extend through the fixing holes of the chassis and then engage in the corresponding through holes of the plate, to fix the heat dissipating device to the chassis.

4. The electronic equipment as claimed in claim 1, wherein a heat conductive block is formed on an opposite side of the plate, a through slot parallel to the plate is defined in the block, one end of a heat pipe is inserted into the through slot of the block, and the other end of the heat pipe is connected to a heat absorbing block contacting with an electronic device installed in the chassis.

5. The electronic equipment as claimed in claim 4, wherein the heat pipe is generally L-shaped.

6. The electronic equipment as claimed in claim 4, wherein the portion of the heat pipe inserted into the through slot of the block is coated with tin paste or tinfoil to reduce the thermal resistance between the heat pipe and the block.

7. A heat dissipating device comprising:
a plate comprising two opposite sides, the plate defining a plurality of vents therein perpendicularly through the sides thereof; and
a plurality of parallel fins perpendicularly projecting from one of the sides of the plate, each two of the fins defining a channel therebetween in communication with the corresponding vents of the plate.

8. The heat dissipating device as claimed in claim 7, wherein at least two tabs extends from the plate of the heat dissipating device, and each of the tabs defines a through hole therein.

9. The heat dissipating device as claimed in claim 7, wherein a heat conductive block is formed on an opposite side of the plate, a through slot parallel to the plate is defined in the block, one end of a heat pipe is inserted into the through slot of the block, and the other end of the heat pipe is connected to a heat absorbing block.

10. The heat dissipating device as claimed in claim 9, wherein the heat pipe is generally L-shaped.

11. The heat dissipating device as claimed in claim 9, wherein the portion of the heat pipe inserted into the through slot of the block is coated with tin paste or tinfoil to reduce the thermal resistance between the heat pipe and the block.
